(19) United States
(12) Patent Application Publication
(10) Pub. No.: US 2024/0422899 A1
(43) Pub. Date: Dec. 19, 2024

(54) ENVIRONMENTALLY FRIENDLY MULTI-LAYER PRINTED CIRCUIT BOARD

(71) Applicant: Intel Corporation, Santa Clara, CA (US)

(72) Inventors: Srinivas B REDDY, Bangalore (IN); Jayprakash THAKUR, Bangalore (IN); Arvind S, Bangalore (IN); Rajasekar A, Nagercoil (IN); Bindu Prabhakar RAO, Bangalore (IN); Pali BARMATE, Balaghat (IN)

(21) Appl. No.: 18/335,145

(22) Filed: Jun. 15, 2023

(51) Int. Cl. H05K 1/02; H05K 1/03; H05K 3/46

(52) U.S. Cl. CPC H05K 1/0298; H05K 1/038; H05K 1/0386; H05K 3/4602

(57) ABSTRACT

The present disclosure generally relates to a multi-layer printed circuit board. The multi-layer printed circuit board may include a core layer and a first prepreg layer adjacent the core layer. The core layer may include a first biodegradable material sandwiched between two electrically conducting layers. A method for forming a multi-layer printed circuit board is also provided herein.

### BACKGROUND

Printed circuit boards (PCB) may include multiple layers, such as a core layer, a prepreg layer, and electrically conducting layers. The core layer or the prepreg layer may contain a dielectric material, for example, a flame retardant fiber glass material commonly known as FR4. The FR4 fiber glass material used between the PCB layers is not recyclable and does not allow separation of individual PCB layers and components. Recycle of PCB is done by crushing and shredding the PCB including its components. Metal and fiber in the form of powder may be separated out using blowers. This recycling process uses hazardous chemicals for cleaning and consumes a lot of power for the crushing and separation process. The amount of metal that can be recycled with this process is very low and a lot of the PCB materials may end up in landfill.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a cross-sectional view of a multi-layer printed circuit board according to an aspect of the present disclosure;

FIG. 1B shows a cross-sectional view of a multi-layer printed circuit board according to another aspect of the present disclosure; and

FIG. 2 shows a flow chart illustrating a method for forming a multi-layer printed circuit board according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

Present disclosure may attempt to address hazardous chemicals and high power consumption issues of existing solutions by designing and fabricating various composites components with a bio-based or biodegradable reinforcement. The biodegradable reinforcement may enable use of low energy-intensive solvent rather than crushing to separate individual PCB components.

The present disclosure generally relates to a multi-layer printed circuit board. The multi-layer printed circuit board may include a core layer. The multi-layer printed circuit board may further include a first prepreg layer adjacent the core layer. The core layer may include a first biodegradable material sandwiched between two electrically conducting layers.

In various aspects, the first prepreg layer may include a second biodegradable material sandwiched between two dielectric layers.

In various aspects, the multi-layer printed circuit board may further include a second prepreg layer adjacent the core layer such that the core layer may be sandwiched between the first prepreg layer and the second prepreg layer.

In various aspects, the second prepreg layer may include a third biodegradable material sandwiched between two dielectric layers.

The present disclosure also generally relates to a method for forming a multi-layer printed circuit board. The method may include forming a core layer and a first prepreg layer adjacent the core layer. The forming of the core layer may include placing a first biodegradable material between two electrically conducting layers.

The present disclosure further relates to a multi-layer printed circuit board, which may include a core layer and a prepreg layer, the core layer and prepreg layer may be joined to each other. The core layer may include a separating layer for separating the prepreg layer from the core layer upon dissolution in a solvent.

To more readily understand and put into practical effect the present disclosure, particular aspects will now be described by way of examples and not limitations, and with reference to the drawings. For the sake of brevity, duplicate descriptions of features and properties may be omitted.

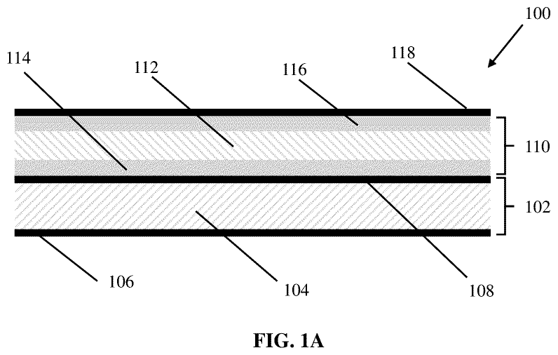

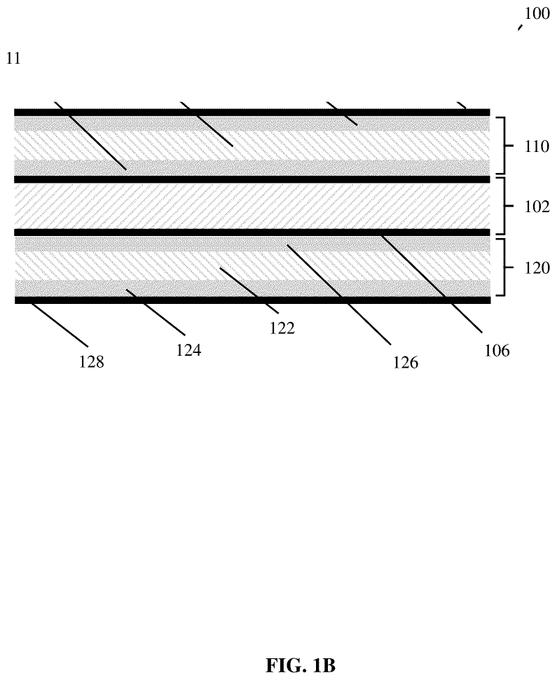

FIG. 1A shows a cross-sectional view of a multi-layer printed circuit board according to an aspect of the present disclosure.

FIG. 1A shows a multi-layer printed circuit board 100 in one aspect. The multi-layer printed circuit board 100 may form part of a semiconductor package.

The multi-layer printed circuit board 100 may include a core layer 102. The core layer 102 may include a biodegradable material 104. The core layer 102 may further include electrically conducting layers 106, 108, such as copper. The core layer 102 may further include a thin dielectric layer of cured fiberglass-epoxy resin (i.e., FR4) that may be separated from other layers (e.g., prepreg layers) by the electrically conducting layers 106, 108.

In the aspect shown in FIG. 1A, the biodegradable material 104 and the electrically conducting layers 106, 108 may be arranged such that the biodegradable material 104 may be sandwiched between the two electrically conducting layers 106, 108 so as to form the core layer 102.

The multi-layer printed circuit board 100 may also include a first prepreg layer 110. The first prepreg layer 110 may be placed adjacent the core layer 102. In the aspect shown in FIG. 1A, the first prepreg layer 110 may be in direct contact with the electrically conducting layer 108. The first prepreg layer 110 may include an uncured fiberglass-epoxy resin, which may be cured to form a dielectric layer by application of pressure or heat.

The first prepreg layer 110 may include a biodegradable material 112. The first prepreg layer 110 may further include dielectric layers 114, 116, such as an epoxy resin.

In the aspect shown in FIG. 1A, the biodegradable material 112 and the dielectric layers 114, 116 may be arranged such that the biodegradable material 112 may be sandwiched between the two dielectric layers 114, 116 so as to form the first prepreg layer 110.

The multi-layer printed circuit board 100 may also include an outer electrically conducting layer 118 on the first prepreg layer 110. The outer electrically conducting layer 118 may include copper.

The biodegradable material to be used in the multi-layer printed circuit board 100 should meet impedance and reliability requirements, as well as dielectric constant requirements for high-speed input/output signals. This may require extraction and isolation of high molecular weight biodegradable nanocellulose and tailoring the biodegradability of nanocellulose by modifying the chemical architecture. The aging characteristics of biodegradable material were tuned by analyzing the biodegradability under UV (A, B, C), heat, RH, and soil. It is herein proposed to use biodegradable materials made of natural waste like jute, linen or areca nut husk in the core layer 102 and in the first prepreg layer 110. Alternatively, the biodegradable materials may include paper and cardboard. These materials may readily dissolve in hot water and may be used to separate individual layers in the multi-layer printed circuit board 100, thereby enabling copper separation and reuse. This may reduce the multi-layer printed circuit board 100 material getting into landfill.

FIG. 1B shows a multi-layer printed circuit board 100 in another aspect, which may be an extension of the aspect shown in FIG. 1A. Various components and layers of the multi-layer printed circuit board 100 have been described above and are not repeated hereinafter for brevity.

In this aspect shown in FIG. 1B, the multi-layer printed circuit board 100 may further include a second prepreg layer 120. The second prepreg layer 120 may be placed adjacent the core layer 102 opposite the first prepreg layer 110. In the aspect shown in FIG. 1B, the second prepreg layer 120 may be in direct contact with the electrically conducting layer 106. In this arrangement, the core layer 102 may be sandwiched between the first prepreg layer 110 and the second prepreg layer 120.

The second prepreg layer 120 may include a biodegradable material 122. The second prepreg layer 120 may further include dielectric layers 124, 126, such as an epoxy resin.

In the aspect shown in FIG. 1B, the biodegradable material 122 and the dielectric layers 124, 126 may be arranged such that the biodegradable material 122 may be sandwiched between the two dielectric layers 124, 126 so as to form the second prepreg layer 120.

The multi-layer printed circuit board 100 may also include an outer electrically conducting layer 128 on the second prepreg layer 120. The outer electrically conducting layer 128 may include copper.

As discussed above, the existing printed circuit boards made up of FR4 fiber glass material are not recyclable and may hinder separation of individual printed circuit board layers to recover and reuse copper components on the printed circuit board. Crushing and strudding of printed circuit boards and separation of metal and fiber uses hazardous chemicals and requires lot of energy. With the use of biodegradable materials in the presently disclosed multi-layer printed circuit board design, metals such as copper could be recovered and reused. This may considerably reduce the amount of printed circuit board material that may end up in landfill, thereby alleviating an important environmental issue. The current printed circuit board design may be easy to manufacture and implement with existing manufacturing processes.

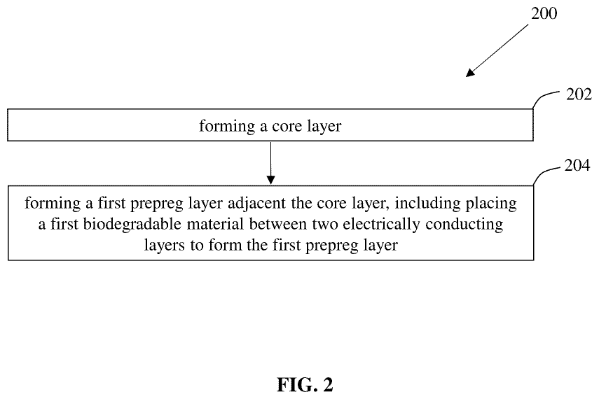

FIG. 2 shows a flow chart illustrating a method 200 of forming a multi-layer printed circuit board according to an aspect of the present disclosure.

At operation 202, the method 200 may include forming a core layer.

At operation 204, the method 200 may also include forming a first prepreg layer adjacent the core layer, including placing a first biodegradable material between two electrically conducting layers to form the first prepreg layer.

### EXAMPLES

Example 1 may include a multi-layer printed circuit board including a core layer and a first prepreg layer adjacent the core layer, wherein the core layer may include a first biodegradable material sandwiched between two electrically conducting layers.

Example 2 may include the multi-layer printed circuit board of example 1 and/or any other example disclosed herein, wherein the first biodegradable material may include jute, linen, areca nut husk, paper or cardboard.

Example 3 may include the multi-layer printed circuit board of example 1 and/or any other example disclosed herein, wherein the first prepreg layer may include a second biodegradable material sandwiched between two dielectric layers.

Example 4 may include the multi-layer printed circuit board of example 3 and/or any other example disclosed herein, wherein the second biodegradable material may include jute, linen, areca nut husk, paper or cardboard.

Example 5 may include the multi-layer printed circuit board of example 1 and/or any other example disclosed herein, further including a second prepreg layer adjacent the core layer such that the core layer may be sandwiched between the first prepreg layer and the second prepreg layer.

Example 6 may include the multi-layer printed circuit board of example 5 and/or any other example disclosed herein, wherein the second prepreg layer may include a third biodegradable material sandwiched between two dielectric layers.

Example 7 may include the multi-layer printed circuit board of example 6 and/or any other example disclosed herein, wherein the third biodegradable material may include jute, linen, areca nut husk, paper or cardboard.

Example 8 may include the multi-layer printed circuit board of example 5 and/or any other example disclosed herein, further including a first outer electrically conducting layer on the first prepreg layer, a second outer electrically conducting layer on the second prepreg layer such that the first prepreg layer, the core and the second prepreg layer may be sandwiched between the first outer electrically conducting layer and the second outer electrically conducting layer.

Example 9 may include the multi-layer printed circuit board of example 8 and/or any other example disclosed herein, wherein the first outer electrically conducting layer or the second outer electrically conducting layer may include copper.

Example 10 may include a method including forming a core layer and forming a first prepreg layer adjacent the core layer, wherein forming the core layer may include placing a first biodegradable material between two electrically conducting layers.

Example 11 may include the method of example 10 and/or any other example disclosed herein, wherein the first biodegradable material may include jute, linen, areca nut husk, paper or cardboard.

Example 12 may include the method of example 10 and/or any other example disclosed herein, wherein forming the first prepreg layer may include placing a second biodegradable material between two dielectric layers.

Example 13 may include the method of example 12 and/or any other example disclosed herein, wherein the second biodegradable material may include jute, linen, areca nut husk, paper or cardboard.

Example 14 may include the method of example 10 and/or any other example disclosed herein, further comprising forming a second prepreg layer adjacent the core layer such that the core layer may be sandwiched between the first prepreg layer and the second prepreg layer.

Example 15 may include the method of example 14 and/or any other example disclosed herein, wherein forming the second prepreg layer may include placing a third biodegradable material between two dielectric layers.

Example 16 may include the method of example 15 and/or any other example disclosed herein, wherein the third biodegradable material may include jute, linen, areca nut husk, paper or cardboard.

Example 17 may include the method of example 15 and/or any other example disclosed herein, further including forming a first outer electrically conducting layer on the first prepreg layer and a second outer electrically conducting layer on the second prepreg layer such that the first prepreg layer, the core and the second prepreg layer may be sandwiched between the first outer electrically conducting layer and the second outer electrically conducting layer.

Example 18 may include the method of example 17 and/or any other example disclosed herein, wherein the first outer electrically conducting layer or the second outer electrically conducting layer may include copper.

Example 19 may include a multi-layer printed circuit board including a core layer and a prepreg layer, the core layer and prepreg layer may be joined to each other, wherein the core layer may include a separating layer for separating the prepreg layer from the core layer upon dissolution in a solvent.

Example 20 may include the multi-layer printed circuit board of example 19 and/or any other example disclosed herein, wherein the separating layer may include jute, linen, areca nut husk, paper or cardboard.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A multi-layer printed circuit board comprising:
a core layer; and
a first prepreg layer adjacent the core layer,
wherein the core layer comprises a first biodegradable material sandwiched between two electrically conducting layers.

2. The multi-layer printed circuit board of claim 1, wherein the first biodegradable material comprises jute, linen, areca nut husk, paper or cardboard.

3. The multi-layer printed circuit board of claim 1, wherein the first prepreg layer comprises a second biodegradable material sandwiched between two dielectric layers.

4. The multi-layer printed circuit board of claim 3, wherein the second biodegradable material comprises jute, linen, areca nut husk, paper or cardboard.

5. The multi-layer printed circuit board of claim 1, further comprising a second prepreg layer adjacent the core layer such that the core layer is sandwiched between the first prepreg layer and the second prepreg layer.

6. The multi-layer printed circuit board of claim 5, wherein the second prepreg layer comprises a third biodegradable material sandwiched between two dielectric layers.

7. The multi-layer printed circuit board of claim 6, wherein the third biodegradable material comprises jute, linen, areca nut husk, paper or cardboard.

8. The multi-layer printed circuit board of claim 5, further comprising a first outer electrically conducting layer on the first prepreg layer, a second outer electrically conducting layer on the second prepreg layer such that the first prepreg layer, the core and the second prepreg layer are sandwiched between the first outer electrically conducting layer and the second outer electrically conducting layer.

9. The multi-layer printed circuit board of claim 8, wherein the first outer electrically conducting layer or the second outer electrically conducting layer comprises copper.

10. A method comprising:
forming a core layer; and
forming a first prepreg layer adjacent the core layer,
wherein forming the core layer comprises placing a first biodegradable material between two electrically conducting layers.

11. The method of claim 10, wherein the first biodegradable material comprises jute, linen, areca nut husk, paper or cardboard.

12. The method of claim 10, wherein forming the first prepreg layer comprises placing a second biodegradable material between two dielectric layers.

13. The method of claim 12, wherein the second biodegradable material comprises jute, linen, areca nut husk, paper or cardboard.

14. The method of claim 10, further comprising forming a second prepreg layer adjacent the core layer such that the core layer is sandwiched between the first prepreg layer and the second prepreg layer.

15. The method of claim 14, wherein forming the second prepreg layer comprises placing a third biodegradable material between two dielectric layers.

16. The method of claim 15, wherein the third biodegradable material comprises jute, linen, areca nut husk, paper or cardboard.

17. The method of claim 15, further comprising forming a first outer electrically conducting layer on the first prepreg layer and a second outer electrically conducting layer on the second prepreg layer such that the first prepreg layer, the core and the second prepreg layer are sandwiched between the first outer electrically conducting layer and the second outer electrically conducting layer.

18. The method of claim 17, wherein the first outer electrically conducting layer or the second outer electrically conducting layer comprises copper.

19. A multi-layer printed circuit board comprising:
a core layer; and
a prepreg layer, the core layer and prepreg layer are joined to each other,
wherein the core layer comprises a separating layer for separating the prepreg layer from the core layer upon dissolution in a solvent.

20. The multi-layer printed circuit board of claim 19, wherein the separating layer comprises jute, linen, areca nut husk, paper or cardboard.
